(19) United States
(12) Patent Application Publication
(10) Pub. No.: US 2005/0067626 A1
(43) Pub. Date: Mar. 31, 2005

(54) LCD having semiconductor components

(75) Inventor: Hsiao-Yi Lin, Hsinchu City (TW)

Correspondence Address: LIU & LIU, 811 WEST 7TH STREET, SUITE 1100, LOS ANGELES, CA, 90017, US

(73) Assignee: Toppoly Optoelectronics Corp.

(21) Appl. No.: 10/945,673

(22) Filed: Sep. 20, 2004

(30) Foreign Application Priority Data
Sep. 25, 2003 (TW) 92126453

(51) Int. Cl. H01L 21/00; H01L 27/15; H01L 31/12; H01L 31/153; H01L 33/00

(52) U.S. Cl. 257/84

(57) ABSTRACT

An LCD having semiconductor components. In one embodiment of the invention, the structure with multiple silicon layers comprises a substrate, a first silicon layer on the substrate, a gate dielectric layer on the first silicon layer, a gate on the gate dielectric layer, an interlayer dielectric layer on the gate, and a second silicon layer on the interlayer dielectric layer.

### BACKGROUND OF THE INVENTION

1. Field of the Invention

The present invention relates to a structure of semiconductor devices in a liquid crystal display (LCD), and in particular to a structure of semiconductor devices in an LCD having semiconductor components.

2. Description of the Related Art

Currently, thin film transistor liquid crystal display (TFT-LCD) technology mainly adopts two kinds of thin-film for fabricating transistors to switch LCD pixel elements. One is amorphous silicon film, and the other is polysilicon film. Polysilicon thin film transistors (TFTs) possesses the advantage of having electron mobility 10-100 times higher than amorphous silicon TFTs. Therefore, driving circuits integrating polysilicon TFTs as pixel switching elements or peripheral driving circuits for an LCD have been investigated and developed.

Polysilicon TFT is fabricated by a low temperature polysilicon (LTPS) process. In the LTPS technology, a polysilicon film is formed by performing excimer laser annealing (ELA) on an amorphous silicon film. Since the process temperature is below 600° C., this technology is applicable to transparent glass substrates. In general, the electron mobility of a polysilicon TFT depends on the grain size of a polysilicon film. Thus, the electron mobility of a polysilicon TFT is increased by increasing the grain size of a polysilicon film. In addition, the grain size of a polysilicon film is related to the laser energy density applied to the amorphous silicon film. Accordingly, it is necessary to measure the grain size of polysilicon film, thereby determining an optimal laser energy density for controlling grain size.

In conventional LCD technology, each semiconductor switch element is disposed on the same plane. In FIG. 1, an LCD includes a glass substrate 100, a first silicon layer 102 formed on the glass substrate 100, a gate dielectric layer 104 on the first silicon layer 102 and the substrate 100, a gate 106 on the gate dielectric layer 104, and inter dielectric layer 108 on the gate 106, and a signal line 110 on a portion of the gate dielectric layer 104. Consequently, LCD usage space and efficiency thereof are not optimized.

### SUMMARY OF THE INVENTION

The invention is to provide an LCD with semiconductor components having multiple silicon layers to save overall space and increase density of semiconductor components. The present invention is directed to a semiconductor component structure in which more than one semiconductor devices, each defined by a silicon layer, are stacked with at least partially overlapping structures. According to the stack structure of the present invention, the LCD can be integrated with more devices, comprising capacitors or resistors.

In one aspect, the present invention provides a semiconductor component that comprises a first semiconductor device defines by a first silicon layer, and a second semiconductor device defined by a second silicon layer, which is at least partially supported above the first semiconductor device. An inter-dielectric layer decouples the first and second semiconductor elements, wherein a portion of the second silicon layer is supported above the inter-dielectric layer. The inter-dielectric layer provides a substrate that partially supports the second silicon layer. The second semiconductor element may comprise a passive element (e.g., resistor, capacitor, memory, etc.) or an active element (e.g., TFT, which may be connected in series to the first semiconductor device).

In one embodiment, the present invention provides a liquid crystal display comprising a substrate, a first semiconductor device defined by a first silicon layer supported above the substrate, a second semiconductor device defined by a second silicon layer partially supported above the first semiconductor device, and an inter-dielectric layer decoupling the first and second semiconductor devices, wherein a portion of the second silicon layer is supported above the inter-dielectric layer. The second semiconductor device comprises at least one of a passive device and an active device. The passive device comprises at least one of a resistor, a capacitor, a floating gate, and a memory device, and the active device comprises at least a TFT.

In another embodiment, the present invention provides an LCD having semiconductor components comprising a substrate, a first silicon layer on the substrate, a gate dielectric layer on the first silicon layer, a gate on the gate dielectric layer, an inter dielectric layer on the gate and the gate dielectric layer and a second silicon layer on the inter dielectric layer, wherein the second silicon layer can be an element of a passive device with stacked structure.

In further another embodiment, the present invention provides another structure of an LCD having semiconductor components comprising a substrate, a first silicon layer on the substrate, a gate dielectric layer on the first silicon layer, a gate on the gate dielectric layer, an inter dielectric layer on the gate and the gate dielectric layer, and a second silicon layer on the inter dielectric layer, wherein the second silicon layer can be an element of an active device with stacked structure.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a cross-section of conventional LTPS TFT;

FIG. 2A is a cross-section of a polysilicon TFT with a resistor of the first embodiment of the present invention;

FIG. 2B is a schematic circuit diagram of FIG. 2A.

FIG. 3A is a cross-section of two serially connected polysilicon TFTs of the second embodiment of the present invention;

FIG. 3B is a schematic circuit diagram of FIG. 3A.

FIG. 4A is a cross-section of a polysilicon TFT with two channels of the third embodiment of the present invention;

FIG. 4B is a schematic circuit diagram of FIG. 4A.

FIG. 5A is a cross-section of a polysilicon TFT with a floating gate and a resistor of the fourth embodiment of the present invention;

FIG. 5B is a schematic circuit diagram of FIG. 5A.

FIG. 6 is a cross-section of two individual polysilicon TFTs of the fifth embodiment of the present invention.

FIG. 7 is a schematic diagram of a display device comprising the LCD in accordance with one embodiment of the present invention.

FIG. 8 is a schematic diagram of an electronic device, incorporating a display comprising the LCD in accordance with one embodiment of the present invention.

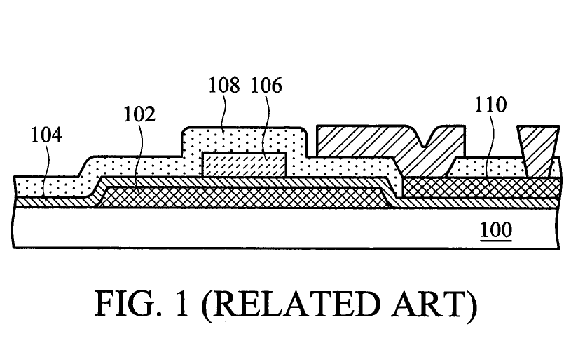

### DETAILED DESCRIPTION OF THE INVENTION

First Embodiment

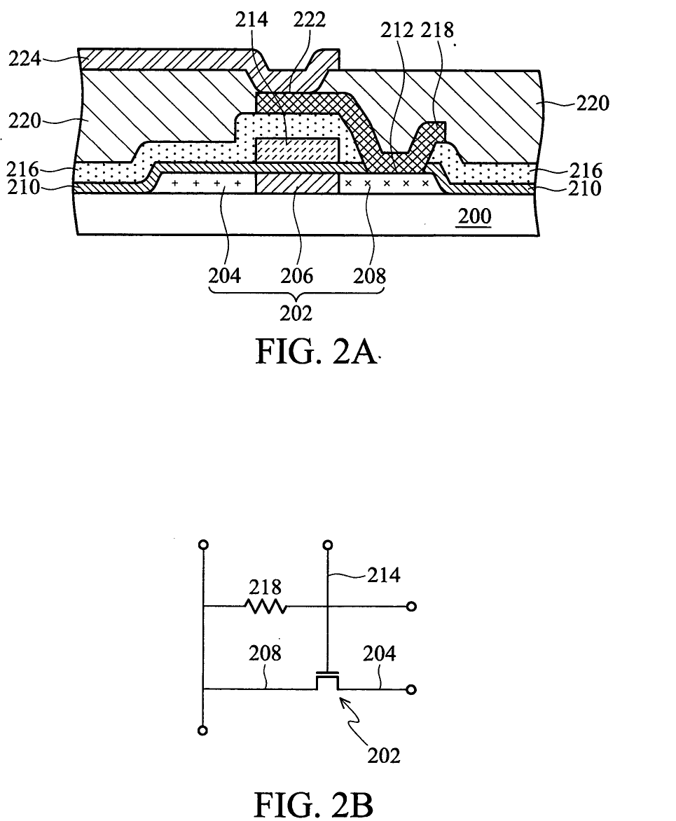

FIG. 2A is a cross-section of a polysilicon TFT with a resistor of the first embodiment of the invention. FIG. 2B is a schematic circuit diagram of FIG. 2A. As shown in FIG. 2A and FIG. 2B, a polysilicon TFT with a resistor is disclosed in the following elements. A first silicon layer 202, such as polysilicon, is preferably formed on a substrate 200 of non-alkaline glass, and more preferably soda lime glass. The first silicon layer 202 includes a first channel region 206 formed between a first source region 204 and a first drain region 208, wherein the first silicon layer 202 may be N-type polysilicon with the first source region 204 and the first drain region 208 doped with N+ ions, or P-type polysilicon with the first source region 204 and the first drain region 208 doped with P+ ions.

A gate dielectric layer 210, such as a silicon nitride layer or a silicon oxide layer, is formed on the first silicon layer 202 and the substrate 200 with an opening 212 over the first source region 204 or the first drain region 208. A gate 214, preferably formed of MoW, is deposited on the gate dielectric layer 210. An inter dielectric layer 216, such as a silicon nitride layer or a silicon oxide layer, is formed on the gate 214 and on the gate dielectric layer 210 excluding the opening 212. A second silicon layer 218 is formed on a portion of the inter dielectric layer 216 and connected to the first silicon layer 202 via the opening 212 to serve as a resistor. A inter metal dielectric layer 220 with an opening 222 over the second silicon layer 218 is formed on the inter dielectric layer 216 and the second silicon layer 218. A conductive layer 224 is connected to the second silicon layer 218 via the opening 224. In FIG. 2A and FIG. 2B, the first silicon layer 202 is a active layer of the TFT. The second silicon layer 218 acts as a resistor, electrically connected to the TFT 202 by the first drain region 208.

Second Embodiment

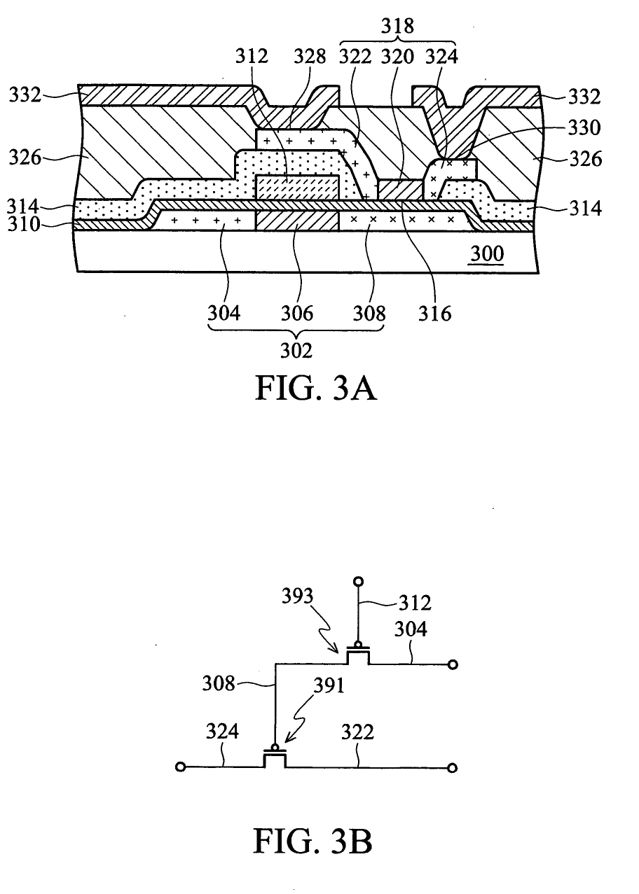

FIG. 3A is a cross-section of two serially connected polysilicon TFTs of the second embodiment of the invention. FIG. 3B is a schematic circuit diagram of FIG. 3A. As shown in FIG. 3A and FIG. 3B, two serially connected polysilicon TFTs comprises the following elements. A first silicon layer 302, such as polysilicon, is formed on a substrate 300 preferably formed of non-alkaline glass, more preferably soda lime glass. The first silicon layer 302 includes a first channel region 306 formed between a first source region 304 and a first drain region 308, wherein the first silicon layer 302 may be N-type polysilicon with the first source region 304 and the first drain region 308 doped with N+ ions, or P-type polysilicon with the first source region 304 and the first drain region 308 doped with P+ ions.

A gate dielectric layer 310, such as a silicon nitride layer or a silicon oxide layer, is formed on the first silicon layer 302 and the substrate 300. A gate 312, preferably formed of MoW, is deposited on the gate dielectric layer 310. An inter dielectric layer 314, such as a silicon nitride layer or a silicon oxide layer with an opening 316 over the first drain region 308 is formed on the gate 312. A second silicon layer 318 including a second channel region 320 formed between a second source region 322 and a second drain region 324 is formed on a portion of the inter dielectric layer 314 and connected to the gate dielectric layer 310 via the opening 316. The second silicon layer 318 may be N-type polysilicon with the second source region 322 and the second drain region 324 doped with N+ ions, or P-type polysilicon with the second source region 322 and the second drain region 324 doped with P+ ions.

A inter metal dielectric layer 326 with the first opening 328 over the second source region 322 and the second opening 330 over the second drain region 324 is formed on the inter dielectric layer 314 and the second silicon layer 318. A conductive layer 332 is connected to the second source region 322 via the first opening 328 and the second drain region 324 via the second opening 330.

In FIGS. 3A and 3B, the two TFTs 391 and 393 are serially connected by the first drain electrode 308 of first TFT 393, in which the first drain electrode 308 controls the second TFT 391. The first silicon layer 302 acts as an active layer of the first TFT 393, and the second silicon active layer 318 as an active layer of the second TFT 391.

Third Embodiment

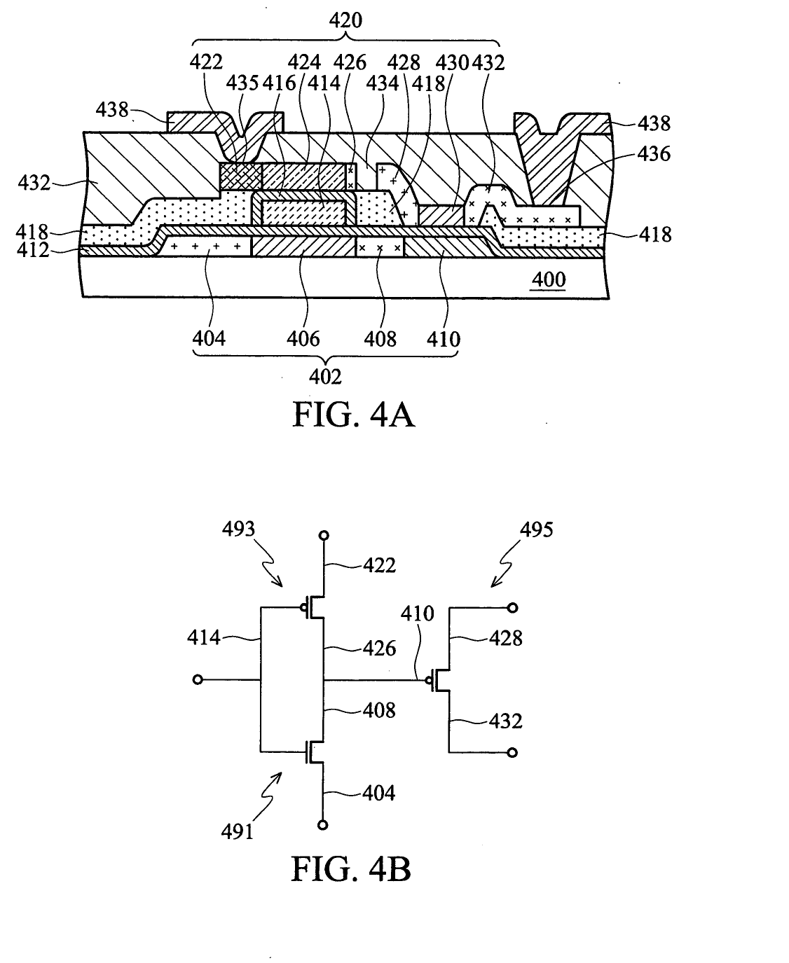

FIG. 4A is a cross-section of a polysilicon TFT with two channels of the third embodiment of the invention. FIG. 4B is a schematic circuit diagram of FIG. 4A. As shown in FIGS. 4A and 4B, a polysilicon TFT with two channels includes subsequent elements. A first silicon layer 402, such as polysilicon, is formed on a substrate 400 preferably formed of non-alkaline glass, more preferably soda lime glass. The first silicon layer 402 includes a first channel region 406 formed between a first source region 404 and a first drain region 408, and the down gate region 410 adjacent to the drain region 408, wherein the first silicon layer 402 may be N-type polysilicon with the first source region 404 and the first drain region 408 doped with N+ ions, or P-type polysilicon with the first source region 404 and the first drain region 408 doped with P+ ions.

A gate dielectric layer 412, such as a silicon nitride layer or a silicon oxide layer, is formed on the first silicon layer 402 and the substrate 400. A gate 414, preferably formed of MoW, is deposited on the gate dielectric layer 412. A top gate dielectric layer 416, such as a silicon nitride layer or a silicon oxide layer, covers the gate 414. An inter dielectric layer 418 formed of silicon nitride or silicon oxide is on the gate dielectric layer 412 excluding the portion over the down gate region 410.

A second silicon layer 420 comprising polysilicon is formed on the top gate dielectric layer 416, the gate dielectric layer 412 over the down gate region 410 and the inter dielectric layer 418, wherein the second silicon layer 420 includes the second channel region 424 over the gate 414 formed between the second source region 422 and the second drain region 426, the third channel region 430 over the down gate region 410, and the third source region 428 and the third drain region 432 beside, wherein the second silicon layer 420 may be N-type polysilicon with the second source region 422, the second drain region 426, the third source region 428, and the third drain region 432 doped with N+ ions, or P-type polysilicon. The down gate region 410 serves as a gate for controlling the third channel 430. The second drain region 426 and the third source region 428 are separated by an opening 434.

A inter metal dielectric layer 419 is formed on the inter dielectric layer 418 and the second silicon layer 420 and fills the opening 434 with a first opening 435 over the second source region 422 and the second opening 436 over the third drain region 432. A conductive layer 438 is connected to the second source region 422 via the first opening 435 and the third source region 432 via the second opening 436.

In FIGS. 4A and 4B, the first TFT 491 and the second TFT 493 are controlled by the same gate electrode 414. The first silicon layer 402 serves as an active layer of the first TFT 491, and the second silicon layer 420 as active layers of the second TFT 493 and the third TFT 495, wherein the third TFT 495 is controlled by the down gate region 410 of the first silicon layer 402.

Fourth Embodiment

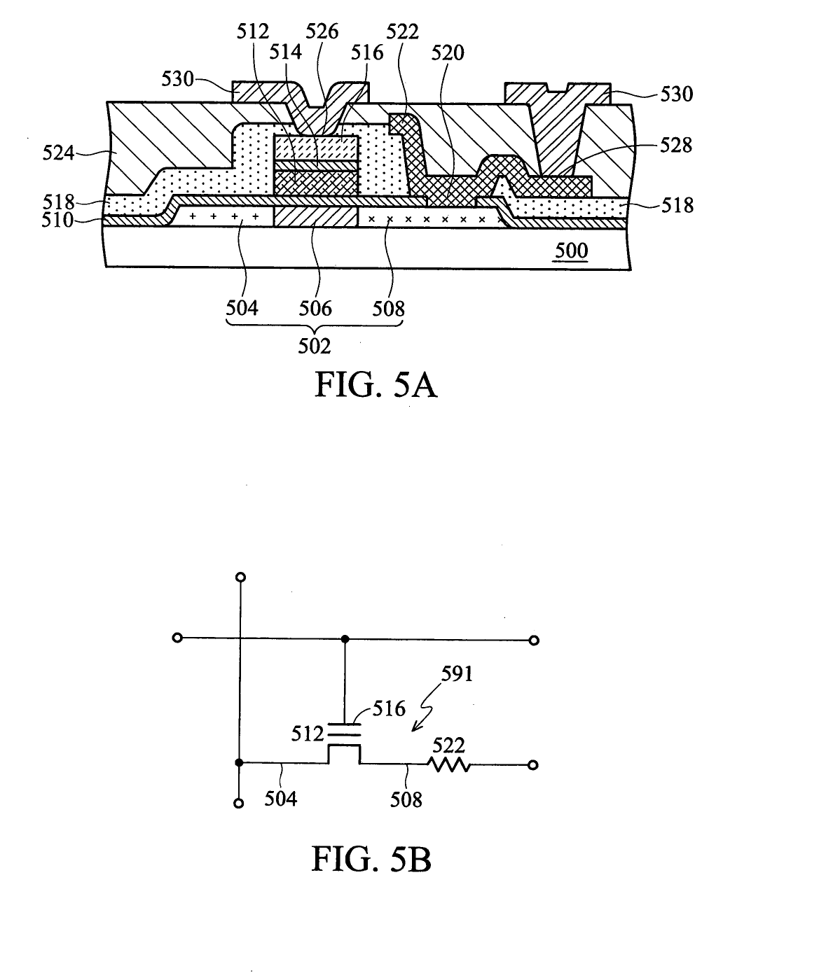

FIG. 5A is a cross-section of a polysilicon TFT with a floating gate and a resistor of the fourth embodiment of the invention. FIG. 5B is a schematic circuit diagram of FIG. 5A.

As shown in FIGS. 5A and 5B, a structure with a resistor and a floating gate includes subsequent elements. A first silicon layer 502, such as polysilicon, is formed on a substrate 500 preferably formed of non-alkaline glass, more preferably soda lime glass. The first silicon layer 502 includes a first channel region 506 formed between a first source region 504 and a first drain region 508, wherein the first silicon layer 502 may be N-type polysilicon with the first source region 504 and the first drain region 508 doped with N+ ions, or P-type polysilicon with the first source region 504 and the first drain region 508 doped with P+ ions.

A gate dielectric layer 510, such as a silicon nitride layer or a silicon oxide layer, is formed on the first silicon layer 502 and the substrate 500. A floating gate formed on the gate dielectric layer 510 includes a gate silicon layer 512 formed of polysilicon, the first conductive layer 516, and a inter gate dielectric layer 514 therebetween. An inter dielectric layer 518, such as a silicon nitride layer or a silicon oxide layer, is formed on the first conductive layer 516 and the gate dielectric layer 514 with an opening 520 over the first drain region 508. A second silicon layer 522, preferably formed of N-type polysilicon or P-type polysilicon, is disposed on the gate dielectric layer 510 over the first drain region 508 and is extended on the inter dielectric layer 518. An inter metal dielectric layer 524 is formed on the inter dielectric layer 518 and the second silicon layer 522 with a first opening 526 over the first conductive layer 516 and a second opening 528 over the second silicon layer 522. A second conductive layer 530 is connected to the first conductive layer 516 via the first opening 526 and the second silicon layer 522 via the second opening 528, wherein the second silicon layer 522, the gate dielectric layer 510 and the first silicon layer 502 form a capacitor.

In FIGS. 5A and 5B, the first silicon layer 502 serves as an active layer of the first TFT 591. The gate controlling the first TFT 591 is a floating gate comprising the gate silicon layer 512 and the first conductive layer 516. The second silicon layer 522 serves as a resistor electrically connected to the drain electrodes 508 of the first TFT 591.

Fifth Embodiment

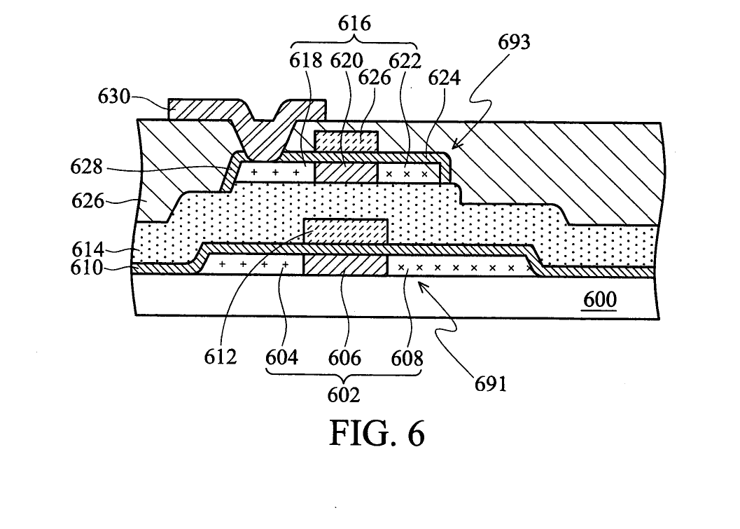

As shown in FIG. 6, a structure with two individual TFT includes subsequent elements. A first silicon layer 602, such as polysilicon, is formed on a substrate 600 preferably formed of non-alkaline glass, more preferably soda lime glass. The first silicon layer 602 includes a first channel region 606 formed between a first source region 604 and a first drain region 608, wherein the first silicon layer 602 may be N-type polysilicon with the first source region 604 and the first drain region 608 doped with N+ ions, or P-type polysilicon with the first source region 604 and the first drain region 608 doped with P+ ions.

A gate dielectric layer 610, such as a silicon nitride layer or a silicon oxide layer, is formed on a first silicon layer 602 and the substrate 600. A first gate 612, preferably formed of MoW, is deposited on the gate dielectric layer 610. An inter dielectric layer 614, such as a silicon nitride layer or a silicon oxide layer, is formed on the gate 612 and on the gate dielectric layer 610. A second silicon layer 616 formed of polysilicon is formed on a portion of the inter dielectric layer 614, including a second channel region 620 formed between a second source region 618 and a second drain region 622, wherein the second silicon layer 616 may be N type or P type.

A top gate dielectric layer 624, preferably formed of silicon nitride or silicon oxide, covers the second silicon layer 616 with a top gate 626 formed of MoW over the second channel region 620. An inter metal dielectric layer 627 is disposed on the inter dielectric layer 614, top gate dielectric layer 624 and the top gate 626 with an opening 628 over the second source region 618, such that a conductive layer 630 is connected to the second source region 618 via the opening 628.

The first silicon layer 602 serves as an active layer of the first TFT 691, and the second silicon layer 602 as an active layer of the second TFT 693, wherein the first TFT 691 and the second TFT 693 are isolated.

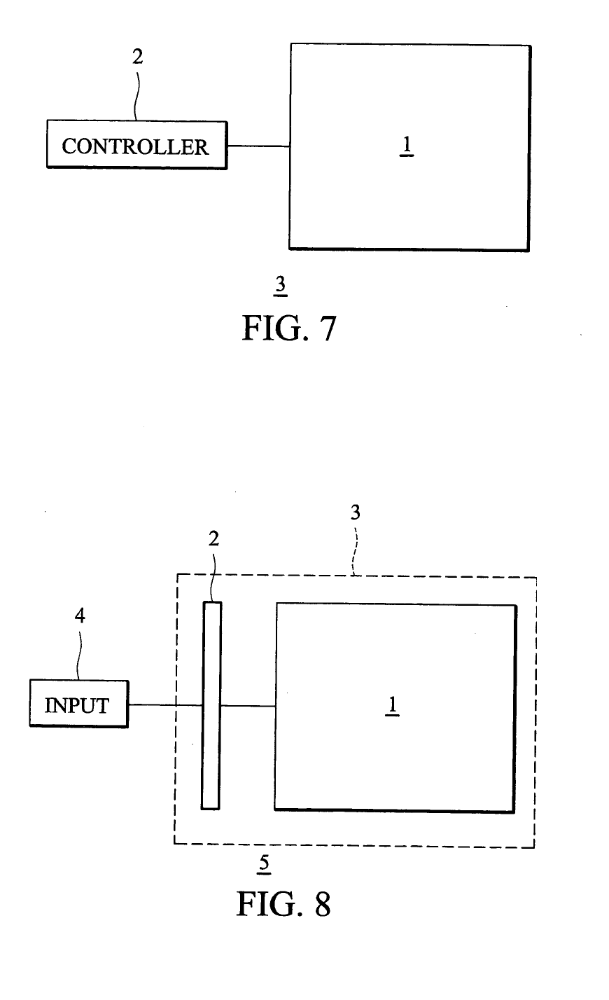

FIG. 7 is a schematic diagram of a display device 3 comprising the LCD in accordance with one embodiment of the present invention. The display panel 1 can be couple to a controller 2, forming a display device 3 as shown in FIG. 7. The controller 3 can comprise a source and a gate driving circuits (not shown) to control the display panel 1 to render image in accordance with an input.

FIG. 8 is a schematic diagram of an electronic device 5, incorporating a display comprising the LCD in accordance with one embodiment of the present invention. An input device 4 is coupled to the controller 2 of the display device 3 shown in FIG. 8 can include a processor or the like to input data to the controller 2 to render an image. The electronic device 5 may be a portable device such as a PDA, notebook computer, tablet computer, cellular phone, or a desktop computer.

Consequently, the invention provides an LCD having semiconductor components to save space and increase efficiency. According to the stack structure of the present invention, the LCD can be integrated with other devices, such as FLASH, SRAM, DRAM, capacitors or resistors.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of thee appended claims should be accorded the broadest interpretation so as to encompass all such modifications and similar arrangements.

1. A liquid crystal display:
a substrate;
a first semiconductor device defined by a first silicon layer, supported above the substrate;
a second semiconductor device defined by a second silicon layer, partially supported above the first semiconductor device; and
an inter-dielectric layer decoupling the first and second semiconductor devices, wherein a portion of the second silicon layer is supported above the inter-dielectric layer.

2. The liquid crystal display as in claim 1, wherein the inter-dielectric layer provides a substrate that partially supports the second silicon layer.

3. The liquid crystal display as in claim 1, wherein the second semiconductor device comprises at least one of a passive device and an active device.

4. The liquid crystal display as in claim 3, wherein the passive device comprises at least one of a resistor, a capacitor, a floating gate, and a memory device.

5. The liquid crystal display as in claim 3, wherein the active device comprises at least a TFT.

6. The liquid crystal display as in claim 5, wherein the TFT is serially coupled to the first semiconductor device.

7. The liquid crystal display as in claim 1, wherein the substrate is a glass substrate.

8. A liquid crystal display comprising:
a substrate;
a first silicon layer on the substrate;
a gate dielectric layer on the first silicon layer;
a gate on the gate dielectric layer;
a portion of the inter dielectric layer on the gate or the gate dielectric layer; and
a portion of the second silicon layer on the inter dielectric layer, wherein the second silicon layer comprising a second channel region, a second source region and a second drain region to form an active device with stacked structure.

9. The liquid crystal display as claimed in claim 8, wherein the first silicon layer and the second silicon layer are formed of polysilicon.

10. The liquid crystal display as claimed in claim 8, wherein the first silicon layer includes a first channel region formed between a first source region and a first drain region; the inter dielectric layer includes an opening over the first drain region; and the second silicon layer is on the inter dielectric layer and fills the opening.

11. The liquid crystal display as claimed in claim 10, further comprising a inter metal dielectric layer on the inter dielectric layer and the second silicon layer with a first opening over the second source region and a second opening over the second drain region.

12. The liquid crystal display as claimed in claim 11, further comprising a conductive layer connected to the second source region via the first opening and the second drain region via the second opening.

13. The liquid crystal display as claimed in claim 8, wherein the first silicon layer includes a first channel region formed between a first source region and a first drain region, and the down gate region adjacent to the first drain region; the inter dielectric layer is on the gate dielectric layer with an opening over the down gate region; the second silicon layer further comprises a third channel region over the down gate region formed between a third source region and a third drain region, wherein the down gate region is a gate for controlling the third channel region.

14. The liquid crystal display as claimed in claim 13, further comprising a top gate dielectric layer covering the gate.

15. The liquid crystal display as claimed in claim 14, wherein the second silicon layer further comprises an opening separating the second drain region and the third source region.

16. The liquid crystal display as claimed in claim 15, further comprising an inter metal dielectric layer deposited on the inter dielectric layer the second silicon layer and the opening with a first opening over the second source region and a second opening over the third drain region.

17. The liquid crystal display as claimed in claim 16, further comprising a conductive layer connected to the second source region via the first opening and the third drain region via the second opening.

18. The liquid crystal display as claimed in claim 15, wherein the first silicon layer comprises a first channel region formed between a the first source region and a first drain region; the second silicon layer is on the inter dielectric layer; the LCD structure further comprises a top gate dielectric layer covering the second silicon layer, and a top gate on the gate dielectric layer over the second channel region.

19. The liquid crystal display as claimed in claim 18, further comprising an inter metal dielectric layer on the inter dielectric layer, the top gate dielectric layer and the top gate, wherein the inter metal dielectric layer and the top gate dielectric layer includes an opening over the second source region.

20. The liquid crystal display as claimed in claim 19, further comprising a conductive layer connected to the second source region via the opening.

21. An liquid crystal display, comprising:
a substrate;
a first silicon layer on the substrate;
a gate dielectric layer on the first silicon layer;
a gate on the gate dielectric layer;
an inter dielectric layer on the gate and the gate dielectric layer; and
a portion of the second silicon layer on the inter dielectric layer, wherein the second silicon layer is an element of a capacitor or a resistor to form a passive device with stacked structure.

22. The liquid crystal display as claimed in claim 21, wherein the first silicon layer and the second silicon layer are formed of polysilicon.

23. The liquid crystal display as claimed in claim 21, wherein the first silicon layer includes a first channel region formed between a first source region and a first drain region; the gate dielectric layer includes an opening over the first source region or the first drain region; the inter dielectric layer is on the gate and the gate dielectric layer excluding the opening; and the second silicon layer fills the opening and is extended on the inter dielectric layer.

24. The liquid crystal display as claimed in claim 21, wherein the first silicon layer includes a first channel region formed between a first source region and a first drain region; and the gate includes a gate silicon layer on the gate dielectric layer over the first channel region, a inter gate dielectric layer on the gate silicon layer and a first conductive layer on the inter gate dielectric layer.

25. The liquid crystal display as claimed in claim 24, wherein the second silicon layer is on the gate dielectric layer over the first drain region, extending on the inter dielectric layer.

26. The liquid crystal display as claimed in claim 25, further comprising an inter metal dielectric layer on the inter dielectric layer and the second silicon layer with a first opening over the first conductive layer and a second opening over the second silicon layer.

27. The liquid crystal display as claimed in claim 26, further comprising a second conductive layer connected to the first conductive layer via the first opening and the second silicon layer via the second opening.

28. A display device, comprising:
a display panel comprising:
a substrate;
a first semiconductor device defined by a first silicon layer, supported above the substrate;
a second semiconductor device defined by a second silicon layer, partially supported above the first semiconductor device; and
an inter-dielectric layer decoupling the first and second semiconductor devices, wherein a portion of the second silicon layer is supported above the inter-dielectric layer; and
a controller coupled to the display panel to control the display panel to render an image in accordance an input.

29. The display device as claimed in claim 28, wherein the second semiconductor device comprises at least one of a passive device and an active device.

30. The display device as claimed in claim 29, wherein the passive device comprises at least one of a resistor, a capacitor, a floating gate, and a memory device.

31. The liquid crystal display as in claim 29, wherein the active device comprises at least a TFT.

32. An electronic device, comprising:
a display panel, comprising:
a substrate;
a first semiconductor device defined by a first silicon layer, supported above the substrate;
a second semiconductor device defined by a second silicon layer, partially supported above the first semiconductor device; and
an inter-dielectric layer decoupling the first and second semiconductor devices, wherein a portion of the second silicon layer is supported above the inter-dielectric layer;
a controller coupled to the display panel to control the display panel to render an image in accordance an input; and
an input device coupled to the controller of the display device to render an image.
